(19) United States
(12) Patent Application Publication
(10) Pub. No.: US 2006/0183312 A1
(43) Pub. Date: Aug. 17, 2006

(54) METHOD OF FORMING CHIP-TYPE LOW-K DIELECTRIC LAYER

(76) Inventors: Shu-Hua Hu, Tai-Chung City (TW); Kuan-Jui Huang, Kao-Hsiung Hsien (TW); Chin-Chang Pan, Taipei Hsien (TW); Shih-Min Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 10/906,977

(22) Filed: Mar. 15, 2005

(30) Foreign Application Priority Data
Feb. 17, 2005 (TW) 094104659

(51) Int. Cl. H01L 21/44; H01L 21/20

(52) U.S. Cl. 438/613; 438/612; 438/381

(57) ABSTRACT

A substrate including a plurality of contact pads is provided. Thereafter, a photosensitive dielectric layer is formed on a surface of the substrate. Subsequently, an exposure-and-development process is preformed to partially remove the photosensitive dielectric layer so as to form a plurality of openings. The openings at least expose the contact pads, and the sidewall of each opening is inclined outwardly.

### BACKGROUND OF INVENTION

1. Field of the Invention

The present invention relates to a method of forming a chip-type low-k dielectric layer, and more particularly, to a method of forming openings with an outwardly-inclined sidewall in a photosensitive dielectric layer, so as to form planar inductor components.

2. Description of the Prior Art

In the fabrication of semiconductor devices, a dielectric layer mainly plays the role of providing an insulating effect. While selecting a suitable dielectric layer, parameters, such as the dielectric constant (k value) and the stress between the dielectric layer and other materials that contact with the dielectric layer, must be considered. In addition, openings are normally formed in the dielectric layer for forming solder bumps or other passive components. For some passive components, particularly planar inductor components, the shape and surface characteristic of the dielectric layer openings are critical to the electric performance, e.g. the Q value.

Please refer to FIG. 1 through FIG. 4. FIG. 1 through FIG. 4 are schematic diagrams illustrating a conventional method of forming a low-k dielectric layer. As shown in FIG. 1, a substrate 10 is provided. The substrate 10 includes a plurality of semiconductor devices 12, and a plurality of contact pads 14 electrically connected to the semiconductor devices 12. As shown in FIG. 2, a dielectric layer 16 is then formed on the surface of the substrate 10. The dielectric layer 16, made of silicon dioxide or benzocyclobutene (BCB), covers both the substrate 10 and the contact pads 14.

As shown in FIG. 3, a photoresist layer (not shown) is disposed on the surface of the dielectric layer 16. Subsequently, an exposure-and-development process is carried out to form a photoresist pattern 18 on the dielectric layer 16 for patterning dielectric layer openings. Thereafter, an etching process is performed utilizing the photoresist pattern 18 as a hard mask to remove the dielectric layer 16 not protected by the photoresist pattern 18 so as to form a plurality of openings 20 corresponding to the contact pads 14 in the dielectric layer 16. As shown in FIG. 4, the photoresist pattern 18 is finally removed.

It can be seen that the conventional method utilizes the photoresist pattern 18 as a hard mask, and forms the openings 20 by an etching process. However, several drawbacks come with the conventional method. First, it is not very easy to control the etching selection ratio of the photoresist pattern 18 to dielectric layer 16, and thus defects tend to appear in the upper portion of the opening 20. In addition, it is difficult to maintain the etching rate and the end point defect (EPD), and therefore undercut 22 and etching residuals 24 are apt to occur in the bottom portion of the opening 20, as shown in FIG. 3 and FIG. 4.

As long as the shape and the surface characteristic of the dielectric layer openings is degraded, the electrical performance of solder bumps or planar inductor components to be formed successively is seriously affected.

### SUMMARY OF INVENTION

It is therefore a primary object of the claimed invention to provide a method of forming a dielectric layer to overcome the aforementioned problem.

It is another object of the claimed invention to provide a method of forming planar inductor components.

According to the claimed invention, a method of forming a dielectric layer is disclosed. A substrate including a plurality of contact pads is provided. Thereafter, a photosensitive dielectric layer is formed on a surface of the substrate. Subsequently, an exposure-and-development process is preformed to partially remove the photosensitive dielectric layer so as to form a plurality of openings. The openings at least expose the contact pads, and the sidewall of each opening is inclined outwardly.

According to the claimed invention, a method of forming planar inductor components is further disclosed. The method of forming planar inductor components includes:

providing a substrate, the substrate comprising a plurality of contact pads;

forming a photosensitive dielectric layer on a surface of the substrate;

performing an exposure-and-development process to partially remove the photosensitive dielectric layer so as to form a plurality of openings, the openings at least exposing the contact pads, and a sidewall of each opening being inclined outwardly;

forming a diffusion barrier layer and a seed layer on the photosensitive dielectric layer, the diffusion barrier layer covering both the photosensitive dielectric layer and the contact pads;

forming a masking pattern on the seed layer, the masking pattern exposing the openings;

forming a plurality of metal structures on a surface of the seed layer not covered by the masking pattern using a plating technique;

removing the masking pattern, the seed layer, and the diffusion barrier layer not covered by the metal structures; and

forming an anti-oxidation film on a surface of the metal structures;

wherein the metal structures are the planar inductor components.

The present invention utilizes a photosensitive material as the dielectric layer, and thus openings with an outwardly-inclined sidewall can be directly formed by an exposure-and-development process. Consequently, a diffusion barrier layer and a seed layer formed successively have an excellent step coverage effect. This ensures excellent electrical performance of the planar inductor components to be fabricated.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 through FIG. 4 are schematic diagrams illustrating a conventional method of forming a low-k dielectric layer.

FIG. 5 through FIG. 7 are schematic diagrams illustrating a method of forming a chip-type low-k dielectric layer according to a preferred embodiment of the present invention.

FIG. 8 through FIG. 12 are schematic diagrams illustrating a method of forming planar inductor components according to a preferred embodiment of the present invention.

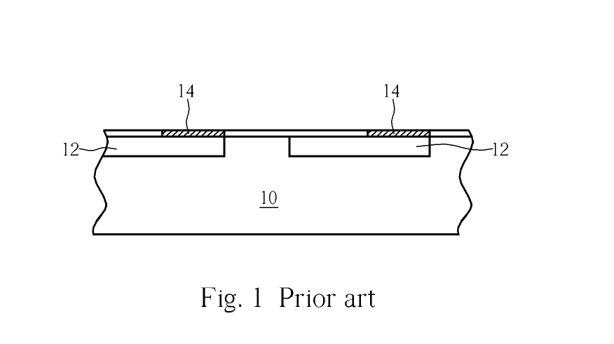

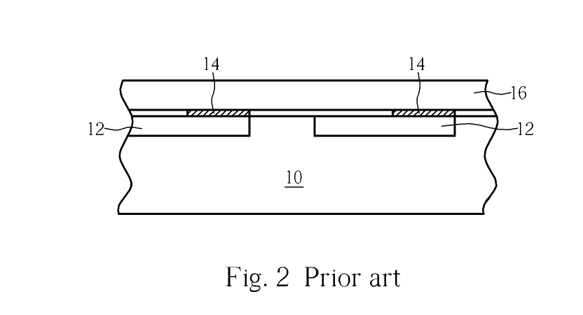

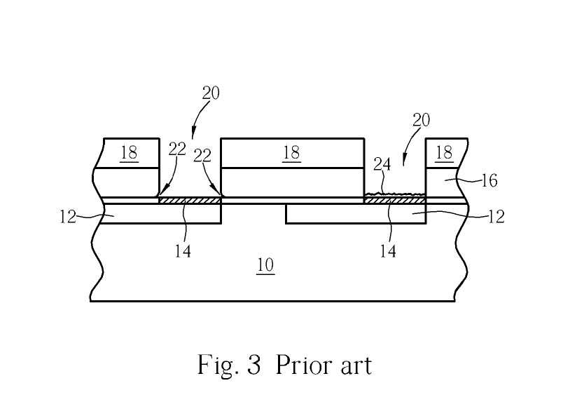

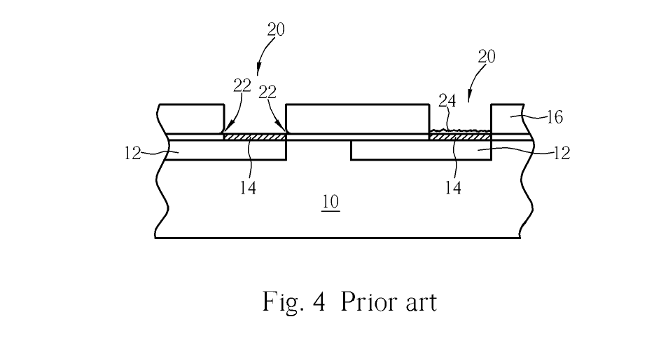

### DETAILED DESCRIPTION

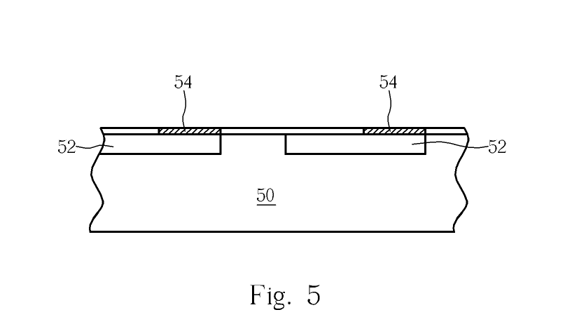

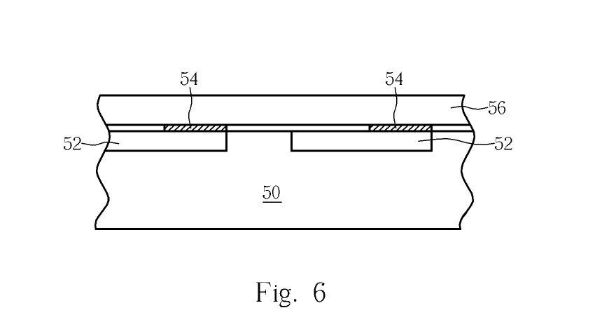

Please refer to FIG. 5 through FIG. 7. FIG. 5 through FIG. 7 are schematic diagrams illustrating a method of forming a chip-type low-k dielectric layer according to a preferred embodiment of the present invention. As shown in FIG. 5, a substrate 50, for instance a semiconductor substrate, is provided. The substrate 50 includes a plurality of semiconductor devices 52, and a plurality of contact pads 54, for instance metal bonding pads, electrically connected to the semiconductor devices 52. As shown in FIG. 6, a photosensitive dielectric layer 56 is formed on the surface of the substrate 50. The photosensitive dielectric layer 56 covers both the substrate 50 and the contact pads 54. Here, the photosensitive dielectric layer 56 is not only dielectric, but also can be patterned by an exposure-and-development process. In this embodiment, the material of the photosensitive dielectric layer 56 is selected from, but not limited to, photosensitive benzocyclobutene (BCB) or low-k polyimide.

Before forming the photosensitive dielectric layer 56, a surface activation process can be selectively performed on the substrate 50 to remove oxide, organic contamination, and particles adhered to the substrate 50, and to increase adhesion between the photosensitive dielectric layer 56 and the substrate 50. The surface activation process can be a wet etching process, a dry etching process, a plasma process, or any combination of these processes. The thickness of the photosensitive dielectric layer 56 can be modified based on electrical requirements. For instance, if planar inductor components are to be fabricated, the thickness of the photosensitive dielectric layer 56 can be adjusted in accordance with the Q value requirement.

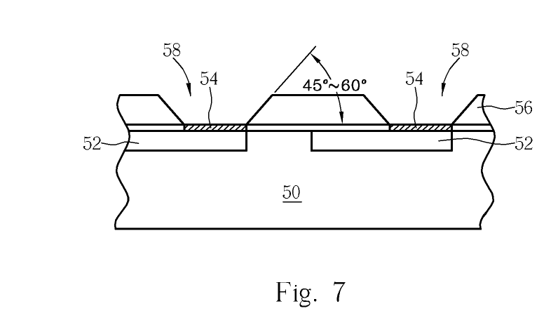

As shown in FIG. 7, an exposure-and-development process is performed to remove a portion of the photosensitive dielectric layer 56 for forming a plurality of openings 58 corresponding to the contact pads 54. In addition, a baking process is carried out to enhance the strength of the photosensitive electric layer 56. By virtue of adjusting light exposure amounts, such as utilizing a halftone mask, the openings 58 having outwardly-inclined sidewalls can be obtained. The outwardly-inclined sidewalls enable thin films formed successively to have a better step coverage effect. In this embodiment, the inclined angle of the sidewall of each opening 58 is between 45 to 60 degrees.

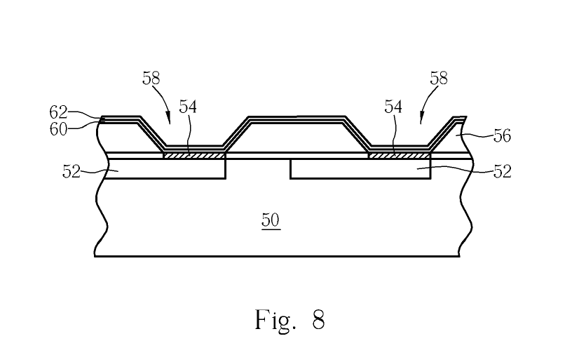

FIG. 5 through FIG. 7 illustrates a method of forming a chip-type low-k dielectric layer. The present invention further provides a method of forming planar inductor components. Please refer to FIG. 8 through FIG. 12 together with FIG. 5 to FIG. 7. FIG. 8 through FIG. 12 are schematic diagrams illustrating a method of forming planar inductor components according to a preferred embodiment of the present invention. As shown in FIG. 8, a diffusion barrier layer 60 and a seed layer are consecutively formed on the photosensitive dielectric layer 56 and the contact pads 54. In this embodiment, the diffusion barrier layer 60 and the seed layer 62 are formed by a sputtering deposition technique, but can also be implemented by other techniques. The diffusion barrier layer 60 can be a single layer, or a multi-layer structure. The material can be tungsten (W), titanium tungsten (TiW), tantalum/tantalum nitride (Ta/TaN), titanium/titanium nitride (Ti/TiN), and so forth. The material of the seed layer 62 depends on the material of the planar inductor components to be fabricated. Normally, gold (Au) or Copper (Cu) is selected.

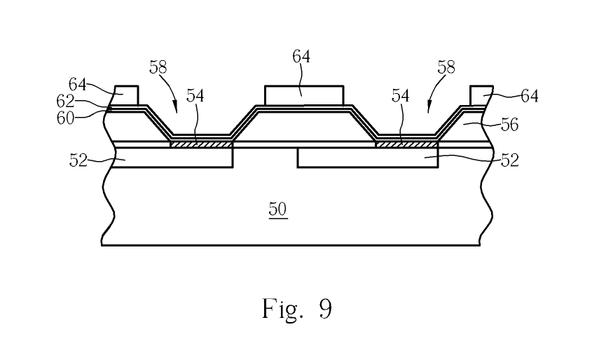

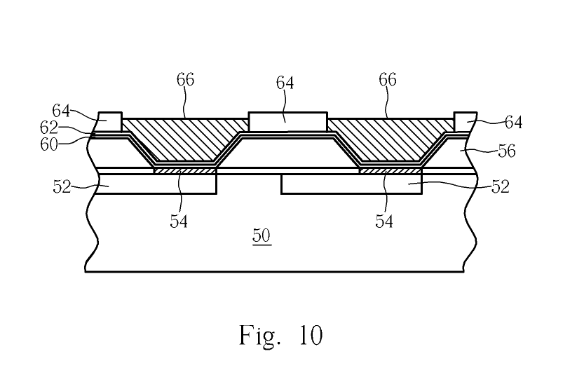

As shown in FIG. 9, a masking pattern 64, e.g. a photoresist pattern, is formed on the surface of the seed layer 62. The masking pattern 64 exposes the openings 58 and areas around each opening 58. As shown in FIG. 10, plating techniques, such as performing an electroplating process or an electroless plating process, is adopted to grow a plurality of metal structures 66 on the surface of the seed layer 62 not covered by the masking pattern 64.

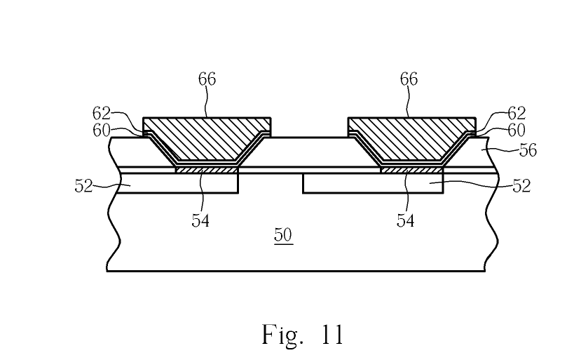

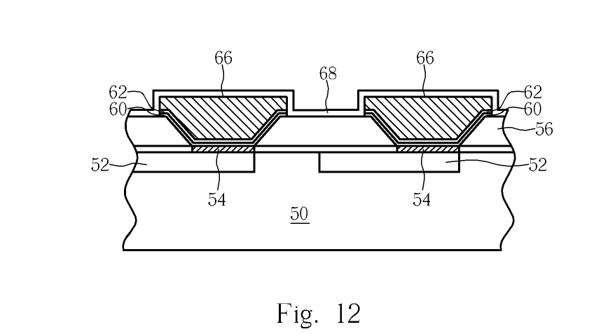

As shown in FIG. 11, the masking pattern 64, the seed layer 62 and the diffusion barrier layer 60 not covered by the metal structures 66 are removed. Subsequently, a high temperature annealing process is performed to strengthen the metal structures 66 and to reduce the resistance. As shown in FIG. 12, an anti-oxidation film 68, such as a photosensitive polymer film, is formed to the surface of the metal structures 66.

The present invention utilizes a photosensitive material as the dielectric layer, and thus openings with outwardly-inclined sidewalls can be directly formed by an exposure-and-development process. Consequently, a diffusion barrier layer and a seed layer formed successively have an excellent step coverage effect. This ensures excellent electrical performance of the planar inductor components to be fabricated. The present invention can also be applied to make other passive components or structures, such as solder bumps.

In comparison with the prior art, the present invention is advantageous for the following reasons:

(a) Simplified manufacture process.

(b) No undercut and residuals.

(c) Excellent step coverage.

(d) No bubbles in the metal structures.

(e) Good electro-migration resistance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a dielectric layer comprising:
providing a substrate, the substrate comprising a plurality of contact pads;
forming a photosensitive dielectric layer on a surface of the substrate; and performing an exposure-and-development process to partially remove the photosensitive dielectric layer so as to form a plurality of openings, the openings at least exposing the contact pads, and a sidewall of each opening being inclined outwardly.

2. The method of claim 1, further comprising, subsequent to forming the openings, forming a plurality of planar inductor components by:
consecutively forming a diffusion barrier layer and a seed layer on the photosensitive dielectric layer, the diffusion barrier layer covering both the photosensitive dielectric layer and the contact pads;
forming a masking pattern on the seed layer, the masking pattern exposing the openings;
electroplating the seed layer not covered by the masking pattern to grow a plurality of metal structures; and
removing the masking pattern, the seed layer, and the diffusion barrier layer not covered by the metal structures;
wherein the metal structures are the planar inductor components.

3. The method of claim 2, further comprising performing a high temperature annealing process subsequent to removing the seed layer and the diffusion barrier layer not covered by the metal structures.

4. The method of claim 2, further comprising forming an anti-oxidation film on the metal structures subsequent to removing the seed layer and the diffusion barrier layer not covered the metal structures.

5. The method of claim 1, wherein the substrate further comprises a plurality of semiconductor devices positioned below the contact pads and electrically connected to the contact pads.

6. The method of claim 1, further comprising performing a surface activation process on the substrate prior to forming the photosensitive dielectric layer.

7. The method of claim 6, wherein the surface activation process is an etching process.

8. The method of claim 1, wherein the material of the photosensitive dielectric layer is photosensitive benzocyclobutene (BCB).

9. The method of claim 1, wherein the material of the photosensitive dielectric layer is low-k (low dielectric constant) polyimide.

10. The method of claim 1, wherein an inclined angle of the sidewall of each opening is approximately between 45 to 60 degrees.

11. A method of forming planar inductor components comprising:
providing a substrate, the substrate comprising a plurality of contact pads;
forming a photosensitive dielectric layer on a surface of the substrate; performing an exposure-and-development process to partially remove the photosensitive dielectric layer so as to form a plurality of openings, the openings at least exposing the contact pads, and a sidewall of each opening being inclined outwardly; forming a diffusion barrier layer and a seed layer on the photosensitive dielectric layer, the diffusion barrier layer covering both the photosensitive dielectric layer and the contact pads;
forming a masking pattern on the seed layer, the masking pattern exposing the openings;
forming a plurality of metal structures on a surface of the seed layer not covered by the masking pattern using a plating technique;
removing the masking pattern, the seed layer, and the diffusion barrier layer not covered by the metal structures; and
forming an anti-oxidation film on a surface of the metal structures;
wherein the metal structures are the planar inductor components.

12. The method of claim 11, wherein the substrate further comprises a plurality of semiconductor devices positioned below the contact pads and electrically connected to the contact pads.

13. The method of claim 11, further comprising performing a surface activation process on the substrate prior to forming the photosensitive dielectric layer.

14. The method of claim 13, wherein the surface activation process is an etching process.

15. The method of claim 11, further comprising performing a high temperature annealing process subsequent to removing the seed layer and the diffusion barrier layer not covered by the metal structures.

16. The method of claim 11, wherein the material of the photosensitive dielectric layer is photosensitive benzocyclobutene (BCB).

17. The method of claim 11, wherein the material of the photosensitive dielectric layer is low-k (low dielectric constant) polyimide.

18. The method of claim 11, wherein an inclined angle of the sidewall of each opening is approximately between 45 to 60 degrees.
